(19) United States
(12) Patent Application Publication
(10) Pub. No.: US 2013/0130486 A1
(43) Pub. Date: May 23, 2013

(54) METHOD OF FORMING SILICIDE LAYERS

(71) Applicant: Shanghai Hua Hong Nec Electronics Co., LTD., Shanghai (CN)

(72) Inventors: Shengan XIAO, Shanghai (CN); Han YU, Shanghai (CN)

(73) Assignee: Shanghai Hua Hong Nec Electronics Co., LTD., Shanghai (CN)

(21) Appl. No.: 13/678,752

(22) Filed: Nov. 16, 2012

(30) Foreign Application Priority Data
Nov. 18, 2011 (CN) 201110366758.3

(51) Int. Cl. H01L 29/66; H01L 21/768

(52) U.S. Cl. CPC H01L 29/665; H01L 21/768
USPC 438/585; 438/682

(57) ABSTRACT

A method of forming silicide layers is disclosed, the method including: providing a silicon substrate which includes at least one first region and at least one second region; depositing a dielectric layer over the silicon substrate; forming at least one opening having a great width/depth ratio in the dielectric layer above the at least one first region, and forming at least one opening having a small width/depth ratio in the dielectric layer above the at least one second region; depositing a metal and performing a high-temperature annealing to form a thick silicide layer in each of the at least one opening above each of the at least one first region and to form a thin silicide layer in each of the at least one opening above each of the at least one second region; removing the remaining metal not formed into the silicide layers.

### CROSS-REFERENCES TO RELATED APPLICATIONS

This application claims the priority of Chinese patent application number 201110366758.3, filed on Nov. 18, 2011, the entire contents of which are incorporated herein by reference.

### TECHNICAL FIELD

The present invention pertains to a method of forming silicide layers in the field of semiconductor integrated circuits.

### BACKGROUND

When a refractory metal reacts with silicon, a blended material, called metal silicide, will be formed. Similarly, a blended material resulted from the reaction of a refractory metal with polysilicon is called polycide. Metal silicides and polycides are collectively referred to as silicides which are a kind of thermally stable metal compounds with low electrical resistivity. Refractory metals commonly used to form silicides are cobalt (Co), molybdenum (Mo), platinum (Pt), tantalum (Ta), titanium (Ti), tungsten (W), nickel (Ni), etc.

In a general case, a silicide process applied to a gate electrode and source/drain regions is intended to result in a low resistance. And when it is adopted in the formation of contact hole electrodes (such as a tungsten plug), it is always for obtaining a good ohmic contact and a low resistance. In a silicide process, a greater thickness of the formed silicide layer leads to the consumption of a larger amount of silicon or polysilicon and thus results in a smaller sheet resistance of the treated region.

In the prior art, silicide layers formed in different regions of a single silicon wafer, and especially those formed in different regions of a single chip, usually have the same thickness. For example, in a metal oxide semiconductor (MOS) transistor, to ensure a very low poly-gate resistance such as lower than 2 ohms per square for a polysilicon gate, a polycide layer with a thickness of nearly 1000 Å is needed to be formed over the polysilicon gate. Accordingly, a silicide layer having almost the same thickness will also be formed above the source/drain regions. However, silicide layers with such a great thickness are excessive for the source/drain regions, which will cause too much consumption of silicon thereof and hence the risk of the occurrence of electric leakage therein. Thus, a method for simultaneously forming a thick polycide layer over the polysilicon gate and thin silicide layers over the source/drain regions on a single chip is desirable.

There is a practical need to form silicide layers having different thicknesses in respective regions of a single silicon substrate. For example, when high-voltage and low-voltage transistors are to be integrated on the same silicon substrate, it is advantageous to have the source-drain junctions of the high-voltage transistors formed deeper than those of the low-voltage ones, and therefore, thicker metal silicide layers are needed to be formed in the source/drain regions of the high-voltage transistors, so as to lower the sheet resistances thereof without increasing the risk of electric leakage.

The existing practice of forming silicide layers with different thicknesses on a single silicon substrate is to repeatedly carry out a process of depositing a metal and annealing it at a high-temperature for a desired number of times so as to form a silicide layer with a desired thickness in a target region at each time. This method has disadvantages of a long production time and high process cost.

### SUMMARY OF THE INVENTION

The present invention is to provide a method of forming silicide layers having different thicknesses on the same silicon substrate at a single time.

To achieve the above objective, a first aspect of the present invention provides a method of forming silicide layers, the method including: providing a silicon substrate which includes at least one first region and at least one second region; depositing a dielectric layer over the silicon substrate, the dielectric layer covering the at least one first region and the at least one second region; forming at least one opening having a great width/depth ratio in the dielectric layer above each of the at least one first region and forming at least one opening having a small width/depth ratio in the dielectric layer above each of the at least one second region; depositing a metal over the silicon substrate and performing a high-temperature annealing process to form a thick silicide layer in each of the at least one opening above each of the at least one first region and to form a thin silicide layer in each of the at least one opening above each of the at least one second region; and removing the remaining metal not formed into the silicide layers.

In an embodiment, among width/depth ratios of all openings formed in the dielectric layer, the greatest width/depth ratio is over two times the smallest one.

In an embodiment, the method further includes removing the dielectric layer after depositing a metal and before performing a high-temperature annealing process.

In an embodiment, the metal has a high mobility whilst the dielectric layer has a low compactness.

A second aspect of the present invention provides a method of forming silicide layers, the method including: providing a silicon substrate which includes at least one first region, at least one second region and at least one third region, each of the at least one third region having a surface higher than that of any of the at least one first region and the at least one second region; depositing a dielectric layer over the silicon substrate, the dielectric layer covering the at least one first region, the at least one second region and the at least one third region; forming at least one opening having a great width/depth ratio in the dielectric layer above each of the at least one first region, forming at least one opening having a small width/depth ratio in the dielectric layer above each of the at least one second region, and removing a portion of the dielectric layer above each of the at least one third region; depositing a metal over the silicon substrate and performing a high-temperature annealing process to form a thick silicide layer in each of the at least one opening above each of the at least one first region, a thin silicide layer in each of the at least one opening above each of the at least one second region, and a thick silicide layer on the surface of each of the at least one third region; and removing the remaining metal not formed into the silicide layers.

In an embodiment, the surface of the third region is a surface of a polysilicon gate formed on the silicon substrate.

A third aspect of the present invention provides a method of forming silicide layers, the method including: providing a silicon substrate which includes at least one first region and at least one second region; depositing a dielectric layer over the silicon substrate, the dielectric layer covering only the at least one second region so that a surface of each of the at least one first region remains uncovered; forming at least one opening having a small width/depth ratio in the dielectric layer above each of the at least one second region; depositing a metal over the silicon substrate and performing a high-temperature annealing process to form a thick silicide layer on the surface of each of the at least one first region and to form a thin silicide layer in each of the at least one opening above each of the at least one second region; and removing the remaining metal not formed into the silicide layers.

In an embodiment, the surface of the first region is a surface of a polysilicon gate formed on the silicon substrate.

A fourth aspect of the present invention provides a method of forming silicide layers, the method including: providing a silicon substrate which includes at least one first region, at least one second region and at least one third region; depositing a dielectric layer over the silicon substrate, the dielectric layer only covering the at least one first region and the at least one second region so that a surface of each of the at least one third region remains uncovered; forming at least one opening having a great width/depth ratio in the dielectric layer above each of the at least one first region and forming at least one opening having a small width/depth ratio in the dielectric layer above each of the at least one second region; depositing a metal over the silicon substrate and performing a high-temperature annealing process to form a thick silicide layer in each of the at least one opening above each of the at least one first region, a thin silicide layer in each of the at least one opening above each of the at least one second region, and a thick silicide layer on the surface of each of the at least one third region; and removing the remaining metal not formed into the silicide layers.

In an embodiment, the surface of the third region is a surface of a polysilicon gate formed on the silicon substrate.

The method of the present invention is able to form silicide layers with different thicknesses at bottoms of openings (or through holes, or trenches) having different width/depth ratios mainly based on the rule that when the corresponding metal is deposited into these openings that have different width/depth ratios, metal layers formed at their bottoms will have different thicknesses. Moreover, when a certain metal such as titanium (Ti) or cobalt (Co) is deposited at the bottom of an opening with a width smaller than, for example, 300 Å or 100 Å, the formed silicide layer will be significantly thinner than proportional. This phenomenon will further increase the adjustability of the thickness of the silicide layer.

### BRIEF DESCRIPTION OF THE DRAWINGS

FIGS. 1a to 1f are schematic diagrams showing steps of a first embodiment according to the present invention.

FIGS. 2a to 2d are schematic diagrams showing steps of a second embodiment according to the present invention.

FIGS. 3a to 3f are schematic diagrams showing steps of a third embodiment according to the present invention.

FIG. 4 is a schematic diagram of a radio-frequency LDMOS device using the method of the present invention.

### DETAILED DESCRIPTION

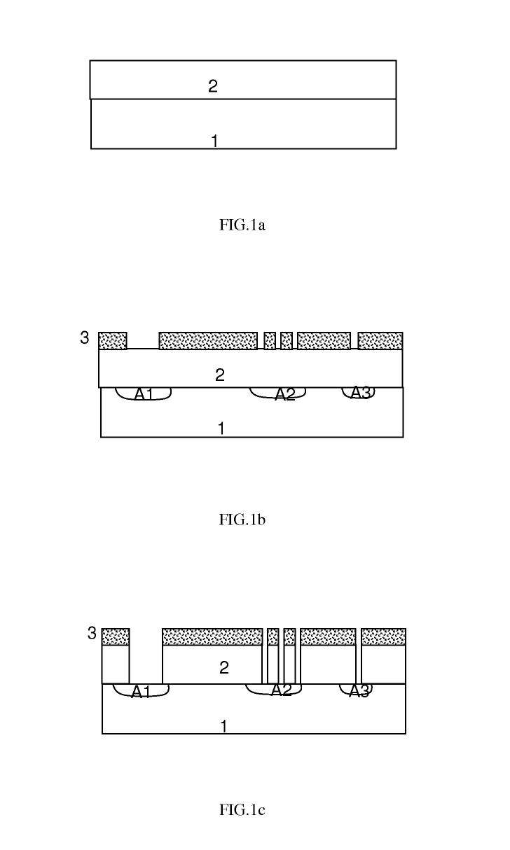

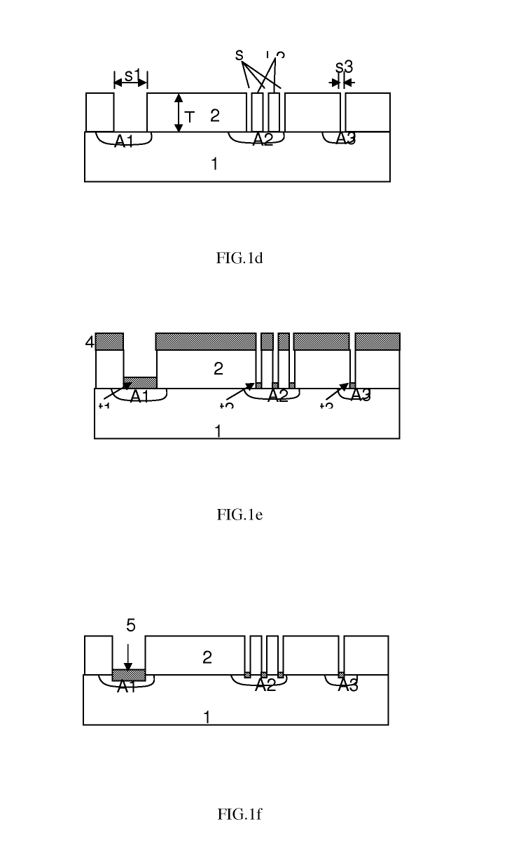

FIGS. 1a to 1f depict a first embodiment of the present invention.

As shown in FIG. 1a, in a first step, a dielectric layer 2 with a thickness of, for example, 0.5 μm to 1 μm is deposited over a semiconductor substrate (which is generally a silicon substrate) 1. The dielectric layer 2 is, for example, a silicon oxide layer.

Referring to FIG. 1b, in a second step, photoresist 3 is coated on the dielectric layer 2 by using a spin-coating process and thereafter the photoresist 3 coated over regions where silicide layers are to be formed are removed in such a manner that, for example, when a thick silicide layer is to be formed in an area A1 and thin silicide layers are to be formed in respective areas A2 and A3, after the photoresist 3 is exposed and developed, there will be formed a pattern including: a wide opening in the area A1 having a width of such as greater than 0.5 μm; and narrow openings in the areas A2 and A3 having widths of such as both smaller than 0.2 μm. These openings may be through holes or trenches, and each of them is formed through the photoresist 3 so as to expose the upper surface of the dielectric layer 2 at the bottom of each opening.

Referring to FIG. 1c, in a third step, the dielectric layer 2 is etched until the upper surface of the substrate 1 is reached, by using the patterned photoresist as an etching mask.

Referring to FIG. 1d, in a fourth step, the photoresist 3 is removed and a pattern is formed in the dielectric layer 2. The pattern includes: an opening formed in the area A1, the opening having a width of s1; a plurality of openings formed in the area A2, the openings having the same width of s2, every adjacent two openings being separated by a distance of L2; and an opening formed in the area A3, the opening having a width of s3. These openings may be through holes or trenches, and each of them is formed through the dielectric layer 2 so as to expose the upper surface of the substrate 1 at the bottom of each opening.

Referring to FIG. 1e, in a fifth step, a metal 4 is deposited over the resultant structure by using, for example, a sputtering process, such that a metal 4 is formed on the upper surface of the dielectric layer 2 and on each portion of the upper surface of the substrate 1 located within an opening. Preferably, the metal 4 is titanium (Ti).

If the thickness of the metal 4 formed on the upper surface of the dielectric layer 2 is 700 Å: when s1 is, for example, 500 Å, a metal 4 with a thickness t1 of 600 Å will be formed within the opening in the area A1; and when s2 is equal to s3 and both of them are, for example, 200 Å, a metal layer 4 with a thickness t2 of smaller than 400 Å will be formed within the openings in the area A2, and a metal layer 4 with a thickness t3 of smaller than 400 Å will be formed within the opening in the area A3.

Referring to FIG. 1f, in a sixth step, a high-temperature annealing process, such as a rapid thermal anneal (RTA) process, is applied and thereby the metal 4 reacts with the silicon substrate 1 and form metal silicide layers 5 in those regions where they contact with each other directly. After that, a silicide layer 5 is formed in each of the openings in the dielectric layer 2. Next, the metal 4 deposited on the dielectric layer 2 as well as the unreacted metal 4 remaining within the openings is removed by using, for example, a wet etching process.

In this step, when the thickness of the metal layer 4 within the opening located in the area A1, namely the opening having a width of s1, is 600 Å, a silicide layer 5 with a thickness of 1000 Å will be formed therein; and when the thicknesses of the metal layers 4 within the openings respectively located in the areas A2 and A3, namely the openings having respective widths of s2 and s3, are smaller than 400 Å, silicide layers 5 with thicknesses of smaller than 600 Å will be formed in corresponding openings.

Further, in this step, when s2 or s3 is smaller than 0.2 μm, the thickness of the silicide layers 5 formed in the openings in the area A2 or the thickness of the silicide layer 5 formed in the opening in the area A3 will be smaller than the proportional value. For example, when s2 is equal to s3 and both of them are 0.15 μm, thicknesses of the silicide layers 5 formed in the openings in the respective areas A2 and A3, namely the openings having respective widths of s2 and s3, are smaller than 300 Å.

In this first embodiment, silicide layers having different thicknesses are formed on the same substrate at a single time. It can be achieved mainly because a metal has different step coverage characteristics when it is deposited on bottoms of openings (or through holes, or trenches) with different width/depth ratios. Such phenomenon results in the formation of metal layers with different thicknesses on the bottoms of the openings which have different width/depth ratios, and thus results in the formation of corresponding silicide layers having different thicknesses.

Overall, a thicker metal layer will be formed in an opening having a greater width/depth ratio and the resultant silicide layer will also have a greater thickness. Otherwise, a thinner metal layer will be formed in an opening having a smaller width/depth ratio and the resultant silicide layer will also have a smaller thickness.

In this first embodiment, as all openings formed in the dielectric layer 2 have the same depth (or height), the comparison between their width/depth ratios is equivalent to that between their widths. Preferably, among these width/depth ratios, the greatest one is over two times the smallest one.

For certain metals, thicknesses of resultant silicide layers from their reaction with silicon are not only dependent on the thicknesses of original metal layers but also depend on widths of openings where the original metal layers are located. When the widths are smaller than certain values, thicknesses of the resultant silicide layers will be smaller than the proportional ones. For example, in this embodiment, if the metal 4 is titanium (Ti) and there is an opening with a width smaller than or equal to 0.3 μm among those formed in the dielectric layer 2, even when all original titanium metal layers within these openings have an identical thickness, the silicide layer 5 formed in this opening will be thinner than those formed in other openings (namely, those having widths greater than 0.3 nm). Similarly, if the metal 4 is cobalt (Co) and there is an opening with a width of smaller than or equal to 0.1 μm among those formed in the dielectric layer 2, the silicide layer 5 formed in it will be thinner than those formed in other openings (namely, those having widths greater than 0.1 μm) even when all original cobalt metal layers have the same thickness. Occurrence of this phenomenon that a certain metal deposited in an opening with a width smaller than a certain value will result in a silicide layer whose thickness is significantly smaller than the proportional one only depends on the kind of the metal and the width of the opening rather than the depth (or height) of the opening.

There is a special case in the formation of silicide layer from metal and silicon, i.e., when the metal 4 is one having a high mobility, such as titanium (Ti), and the dielectric layer is one having a low compactness, such as a loose film produced by using a normal pressure chemical vapor deposition (CVD) method, the formation of silicide layers in the two or more openings in the area A2 will proceed both in vertical and lateral directions if the interval L2 between these openings is smaller than or equal to 0.1 μm. As a result, silicide layers 5 formed under bottoms of the openings in the area A2 will be all joined together, i.e., although these openings are isolated from each other in the dielectric layer 2, the silicide layers 5 formed beneath them are laterally joined.

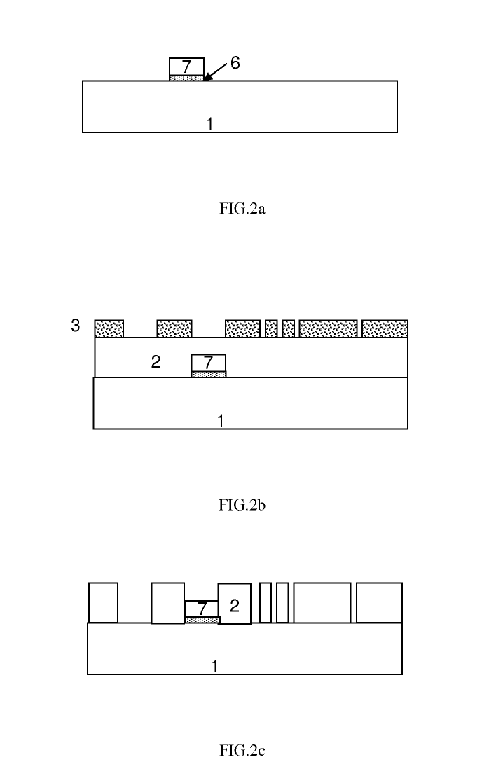

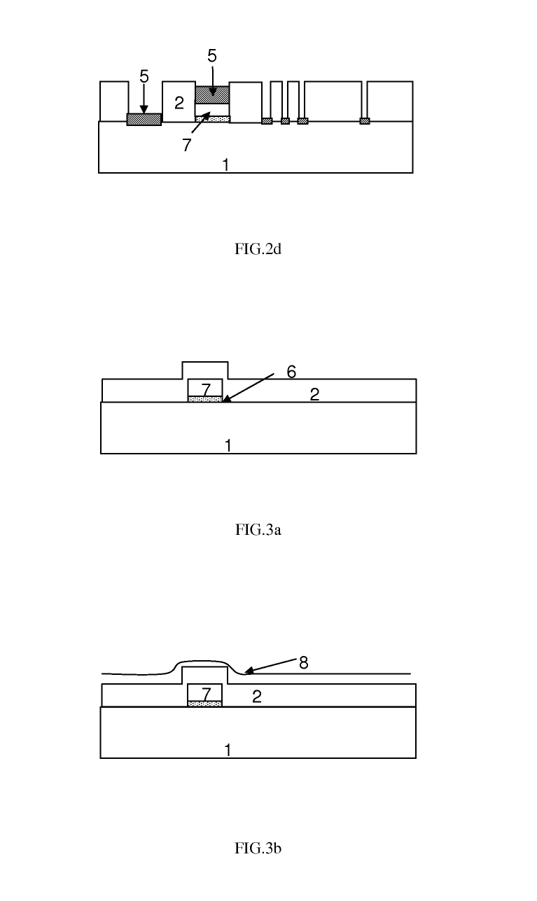

FIGS. 2a to 2d depict a second embodiment of the present invention.

As shown in FIG. 2a, in a first step, a gate oxide 6 is formed over a substrate 1 and a polysilicon gate 7 is formed over the gate oxide 6. The gate oxide 6 has a thickness of, for example, 100 Å to 500 Å, and the polysilicon gate 7 has a thickness of, for example, 3000 Å to 5000 Å.

Referring to FIG. 2b, in a second step, a dielectric layer 2 having a thickness of, for example, 8000 Å to 10000 Å, is deposited over the silicon substrate 1 in such a manner that the upper surface of the resultant dielectric layer 2 is smooth and flat without any protrusions. Next, photoresist 3 is coated over the dielectric layer 2 by using a spin-coating process and thereafter a pattern is formed in the photoresist 3 by using a photolithographic process. The pattern includes large sized openings above regions (including the region of the polysilicon gate 7) where thick silicide layers are to be formed and small sized openings above regions where thin silicide layers are to be formed.

Referring to FIG. 2c, in a third step, the dielectric layer 2 is etched until upper surface of the substrate 1 or upper surface of the polysilicon gate 7 is reached, by using the patterned photoresist as an etching mask. After that, the photoresist 3 is removed and a pattern is formed in the dielectric layer 2. The pattern includes large sized openings in regions (including the region of the polysilicon gate 7) where thick silicide layers are to be formed and small sized openings in regions where thin silicide layers are to be formed. The depth of the opening formed above the polysilicon gate 7 is smaller than the depth of the openings formed in the dielectric layer 2.

Referring to FIG. 2d, in a fourth step, a metal is deposited over the surface of the resultant structure and a high-temperature annealing process is applied, such that the metal reacts with silicon or polysilicon to form metal silicide layers 5 or polycide 5 in those regions where they contact with each other directly. After that, the portion of the metal deposited over the dielectric layer 2 and the unreacted metal remaining within the openings is removed.

After these steps, a thick silicide layer 5 is formed in each large sized opening and a thin silicide layer 5 is formed in each small sized opening.

In the second step of this embodiment, a thicker metal layer will be formed in an opening having a greater width/depth ratio and the resultant silicide layer will also have a greater thickness. Otherwise, a thinner metal layer will be formed in an opening having a smaller width/depth ratio and the resultant silicide layer will also have a smaller thickness. Preferably, among these width/depth ratios, the greatest one is over two times the smallest one.

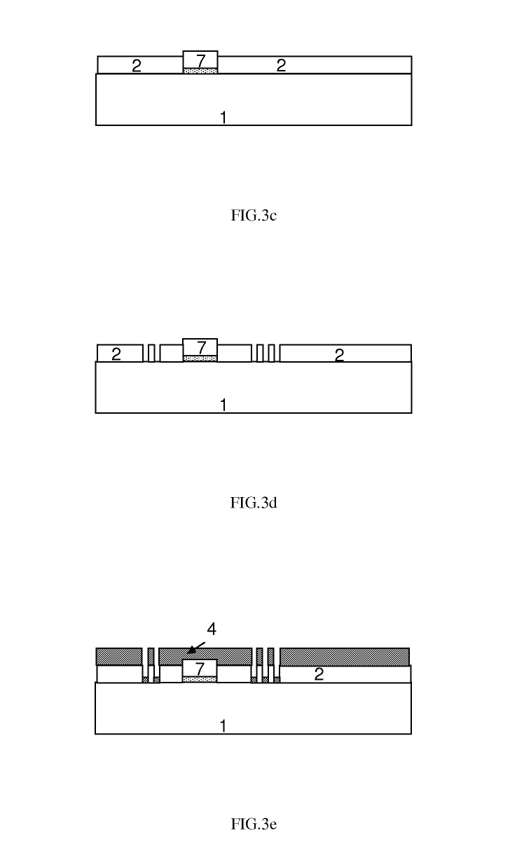

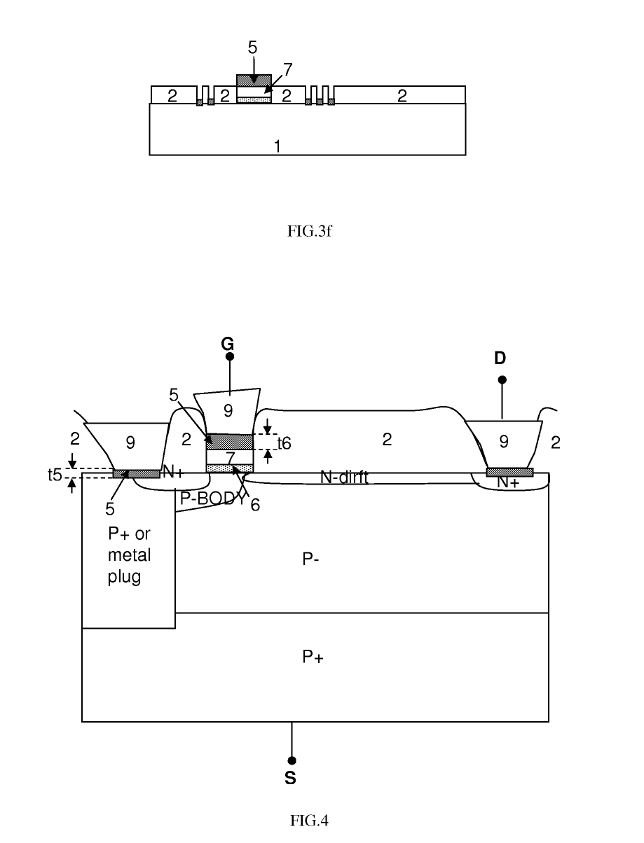

FIGS. 3a to 3f depict a third embodiment of the present invention.

As shown in FIG. 3a, in a first step, a gate oxide 6 is formed over a substrate 1 and a polysilicon gate 7 is formed over the gate oxide 6, and a dielectric layer 2 is deposited over the upper surface of this structure. After that, a protrusion appears on a portion of the dielectric layer 2 just above the polysilicon gate 7. Preferably, the gate oxide 6 has a thickness of, for example, 100 Å to 500 Å; the polysilicon gate 7 has a thickness of, for example, 3000 Å to 5000 Å; and the dielectric layer 2 is, for example, a silicon oxide layer with a thickness of, for example, 8000 Å to 10000 Å.

Referring to FIG. 3b, in a second step, a bottom anti-reflective coating (BARC) layer 8 is coated over the upper surface of the resultant structure by using a spin-coating process. After that, a protrusion having less steepness than that of the last step will appear on a portion of the BARC layer 8 just above the polysilicon gate 7. Optionally, in this step, a photoresist layer may be formed instead of the BARC layer 8, and after the photoresist is spin-coated, a protrusion having less steepness will also be formed above the polysilicon gate 7.

Referring to FIG. 3c, in a third step, the portions of the BARC layer 8 and the dielectric layer 2 just above the polysilicon gate 7 are removed by an etching process and the rest portions of the two layers are retained. Next, the rest portion of the BARC layer 8 is removed by using, for example, a wet etching process. After that, a top portion of the polysilicon gate 7 that protrudes out of the rest portion of the dielectric layer 2 is exposed, i.e., the upper surface as well as portions of side faces of the polysilicon gate 7 higher than the rest portion of the dielectric layer 2 are exposed.

Preferably, this step is carried out in sub-steps as follows: first, a portion of the BARC layer 8 just above the polysilicon gate 7 is removed and the rest portion of the BARC layer 8 is retained; after that, a portion of the dielectric layer 2 above the polysilicon gate 7 is etched by using the rest portion of the BARC layer 8 as a protection; and at last, the rest portion of the BARC layer 8 is removed.

Referring to FIG. 3d, in a fourth step, forming one or more openings in the dielectric layer 2 by photolithographic and etching processes, each opening exposing a portion of the upper surface of the substrate 1 at its bottom.

Referring to FIG. 3e, in a fifth step, a metal 4 is sputtered over the surface of the resultant structure, such that the metal 4 deposits on the upper surface of polysilicon gate 7, the upper surface of the dielectric layer 2 and bottoms of the openings in the dielectric layer 2. Preferably, the metal 4 is titanium (Ti).

Referring to FIG. 3f, in a sixth step, a high-temperature annealing process is applied and thereby the metal 4 reacts with silicon or polysilicon to form metal silicide layers 5 or polycide 5 in those regions where they contact with each other directly. Next, the metal 4 deposited over the dielectric layer 2 and the unreacted metal remaining within the openings is removed.

After these steps, a thick silicide layer 5 is formed in the unshielded region (namely, above the polysilicon gate 7) and in each large sized opening (not shown), and a thin silicide layer 5 is formed in each small sized opening.

In the fourth step of this embodiment, a thicker metal layer will be formed in an opening having a greater width/depth ratio and the resultant silicide layer will also have a greater thickness. Otherwise, a thinner metal layer will be formed in an opening having a smaller width/depth ratio and the resultant silicide layer will also have a smaller thickness. Preferably, among these width/depth ratios, the greatest one is over two times the smallest one.

Further, in these three embodiments, the dielectric layer 2 may be removed by a chemical etching process after depositing the metal and before forming the silicide layers 5 and/or the polycide 5 by a high-temperature annealing process.

In the first embodiment, regions where silicide layers are to be formed are certain regions of the substrate 1 that is situated under the dielectric layer 2; etching processes are performed to form openings in the dielectric layer 2; and the openings have the same depth (or height).

In the second embodiment, where silicide layers are to be formed include the region of the polysilicon gate 7 and certain regions of the substrate 1; both of the polysilicon gate 7 and the substrate 1 are situated under the dielectric layer 2; etching processes are performed to form openings in the dielectric layer 2; and the openings have different depths (or heights).

In the third embodiment, where silicide layers are to be formed include the region of the polysilicon gate 7 and certain regions of the substrate 1; the substrate 1 is situated under the dielectric layer 2, while the upper surface of the polysilicon gate 7 is at a level above the upper surface of a rest portion of the dielectric layer 2 other than the portion formed above the polysilicon gate 7; etching processes are performed to make upper surface of the polysilicon gate 7 be exposed and protrude out of the upper surface of the dielectric layer 2 and to form openings in the dielectric layer 2; and the openings have the same depth (or height).

FIG. 4 schematically illustrates a radio-frequency laterally diffused metal oxide semiconductor (LDMOS) device, to which the method of the present invention is applied, wherein a polycide layer 5 with a thickness t6 of up to 1000 Å is formed over the polysilicon gate 7, and a silicide layer 5 with a thickness t5 of smaller than 500 Å is formed over a source/drain region. Such method of forming suicide layers with different thicknesses on the same device (even on the same silicon wafer) can satisfy the need of the gate G for a very low sheet resistance while eliminating electric leakage risk of the source/drain regions by forming a thin metal silicide layer over the drain D.

While a number of preferred embodiments have been presented in the foregoing description, they are not intended to limit the invention in any way. It will be apparent to those skilled in the art that various modifications and variations can be made without departing from the spirit or scope of the invention. Thus, it is intended that the present invention covers all such modifications, equivalent alternatives and variations.

What is claimed is:

1. A method of forming silicide layers, the method comprising:
providing a silicon substrate which includes at least one first region and at least one second region;
depositing a dielectric layer over the silicon substrate, the dielectric layer covering the at least one first region and the at least one second region;
forming at least one opening having a great width/depth ratio in the dielectric layer above each of the at least one first region and forming at least one opening having a small width/depth ratio in the dielectric layer above each of the at least one second region;
depositing a metal over the silicon substrate and performing a high-temperature annealing process to form a thick silicide layer in each of the at least one opening above each of the at least one first region and to form a thin silicide layer in each of the at least one opening above each of the at least one second region; and
removing the remaining metal not formed into the silicide layers.

2. The method according to claim 1, wherein among the width/depth ratios of all the openings formed in the dielectric layer, the greatest width/depth ratio is over two times the smallest one.

3. The method according to claim 1, further comprising removing the dielectric layer after depositing the metal and before performing the high-temperature annealing process.

4. The method according to claim 1, wherein the metal has a high mobility whilst the dielectric layer has a low compactness.

5. A method of forming silicide layers, the method comprising:
providing a silicon substrate which includes at least one first region, at least one second region and at least one third region, each of the at least one third region having a surface higher than that of any of the at least one first region and the at least one second region;
depositing a dielectric layer over the silicon substrate, the dielectric layer covering the at least one first region, the at least one second region and the at least one third region;
forming at least one opening having a great width/depth ratio in the dielectric layer above each of the at least one first region, forming at least one opening having a small width/depth ratio in the dielectric layer above each of the at least one second region, and removing a portion of the dielectric layer above each of the at least one third region;
depositing a metal over the silicon substrate and performing a high-temperature annealing process to form a thick silicide layer in each of the at least one opening above each of the at least one first region, a thin silicide layer in each of the at least one opening above each of the at least one second region, and a thick silicide layer on the surface of each of the at least one third region; and
removing the remaining metal not formed into the silicide layers.

6. The method according to claim 5, wherein the surface of the third region is a surface of a polysilicon gate formed on the silicon substrate.

7. The method according to claim 5, wherein among the width/depth ratios of all the openings formed above the at least one first region and the at least one second region, the greatest width/depth ratio is over two times the smallest one.

8. The method according to claim 5, further comprising removing the dielectric layer after depositing the metal and before performing the high-temperature annealing process.

9. The method according to claim 5, wherein the metal has a high mobility whilst the dielectric layer has a low compactness.

10. A method of forming silicide layers, the method comprising:
providing a silicon substrate which includes at least one first region and at least one second region;
depositing a dielectric layer over the silicon substrate, the dielectric layer covering only the at least one second region so that a surface of each of the at least one first region remains uncovered;
forming at least one opening having a small width/depth ratio in the dielectric layer above each of the at least one second region;
depositing a metal over the silicon substrate and performing a high-temperature annealing process to form a thick silicide layer on the surface of each of the at least one first region and to form a thin silicide layer in each of the at least one opening above each of the at least one second region; and
removing the remaining metal not formed into the silicide layers.

11. The method according to claim 10, wherein the surface of the first region is a surface of a polysilicon gate formed on the silicon substrate.

12. The method according to claim 10, further comprising removing the dielectric layer after depositing the metal and before performing the high-temperature annealing process.

13. The method according to claim 10, wherein the metal has a high mobility whilst the dielectric layer has a low compactness.

14. A method of forming silicide layers, the method comprising:
providing a silicon substrate which includes at least one first region, at least one second region and at least one third region;
depositing a dielectric layer over the silicon substrate, the dielectric layer only covering the at least one first region and the at least one second region so that a surface of each of the at least one third region remains uncovered;
forming at least one opening having a great width/depth ratio in the dielectric layer above each of the at least one first region and forming at least one opening having a small width/depth ratio in the dielectric layer above each of the at least one second region;
depositing a metal over the silicon substrate and performing a high-temperature annealing process to form a thick silicide layer in each of the at least one opening above each of the at least one first region, a thin silicide layer in each of the at least one opening above each of the at least one second region, and a thick silicide layer on the surface of each of the at least one third region; and
removing the remaining metal not formed into the silicide layers.

15. The method according to claim 14, wherein the surface of the third region is a surface of a polysilicon gate formed on the silicon substrate.

16. The method according to claim 14, wherein among the width/depth ratios of all the openings formed in the dielectric layer, the greatest width/depth ratio is over two times the smallest one.

17. The method according to claim 14, further comprising removing the dielectric layer after depositing the metal and before performing the high-temperature annealing process.

18. The method according to claim 14, wherein the metal has a high mobility whilst the dielectric layer has a low compactness.
